(19) United States
(12) Patent Application Publication
(10) Pub. No.: US 2016/0079474 A1
(43) Pub. Date: Mar. 17, 2016

(54) SEMICONDUCTOR LIGHT EMITTING DEVICE AND METHOD OF MANUFACTURING THE SAME

(71) Applicant: Seoul Viosys Co., Ltd., Ansan-si (KR)

(72) Inventors: Duck II Suh, Ansan-si (KR); Kyoung Wan Kim, Ansan-si (KR); Yeo Jin Yoon, Ansan-si (KR); Ye Seul Kim, Ansan-si (KR); Ji Hye Kim, Ansan-si (KR)

(21) Appl. No.: 14/952,641

(22) Filed: Nov. 25, 2015

Related U.S. Application Data
(63) Continuation of application No. 14/126,638, filed on Dec. 16, 2013.

(30) Foreign Application Priority Data
Jun. 15, 2011 (KR) 10-2011-0058083

(51) Int. Cl. H01L 33/24; H01L 33/32; H01L 33/38; H01L 33/22

(52) U.S. Cl. CPC H01L 33/24; H01L 33/22; H01L 33/32; H01L 33/38; H01L 2933/0091

(57) ABSTRACT

This invention relates to a semiconductor light emitting device which has superior lateral light extraction efficiency, and to a method of manufacturing the same. The semiconductor light emitting device includes a sapphire substrate and a light emitting structure formed on an upper surface of the sapphire substrate and including a plurality of nitride epitaxial layers including an active layer which produces light, wherein at least one side surface of the light emitting structure is formed as an inclined surface which creates an acute angle relative to the upper surface of the sapphire substrate. In some embodiments, at least one modification region can be formed in a horizontal direction on at least one side surface of the sapphire substrate using laser irradiation.

### TECHNICAL FIELD

The present invention relates to a semiconductor light emitting device, and, more particularly, to a semiconductor light emitting device which has superior lateral light extraction efficiency and which allows easy cut of a substrate, and to a method of manufacturing the same.

### BACKGROUND ART

Since the development of nitride semiconductor light emitting devices (e.g. Group 3 nitride semiconductor light emitting devices or laser diodes), they have been receiving attention as a main light source of the next generation in the field of backlights for displays, flashes for cameras, illuminators, etc. As the application field of nitride semiconductor light emitting devices becomes wider, a lot of effort is being directed to increasing luminance and light emission efficiency.

Typically, semiconductor light emitting devices are required to have improved inner quantum efficiency and light extraction efficiency in order to increase light emission efficiency. The inner quantum efficiency is related to properties pertaining to epitaxial growth and the structural design of a substrate, and the light extraction efficiency may be optimized by epitaxial growth and processing techniques.

In particular, it is difficult to increase the light extraction efficiency of the semiconductor light emitting device because light generated from an active layer positioned in the device is totally reflected due to a difference in external refractive index and thus is absorbed or disappears, or such light is absorbed by inner crystal defects and thus converted into heat energy. A critical angle at which light may travel between two media having different refractive indexes may be determined based on the law of refraction (Snells law), and in the case of a nitride-based semiconductor material, its refractive index is as high as about 2.5, and thus, a critical angle at which light produced from the active layer may be emitted outside the device is about 23°, which is very limited. Accordingly in the semiconductor light emitting device, the total reflection of light which is incident on the interface of the device at an angle greater than the critical angle continues until such light is absorbed by the inside of the device, followed by converting the light into heat energy, so that the light extraction efficiency is as low as 30˜40%.

Therefore, research and development into a variety of methods of increasing the light extraction efficiency of semiconductor light emitting devices is ongoing in the art.

### DISCLOSURE

### Technical Problem

Accordingly, the present invention has been made keeping in mind the above problems occurring in the related art, and the present invention is intended to provide a semiconductor light emitting device which is capable of increasing lateral light extraction efficiency.

In addition, the present invention is intended to provide a method of manufacturing the semiconductor light emitting device.

### Technical Solution

Therefore, an aspect of the present invention provides a semiconductor light emitting device, comprising a sapphire substrate; and a light emitting structure formed on an upper surface of the sapphire substrate, the light emitting structure comprising a plurality of nitride epitaxial layers including an active layer which produces light, wherein at least one side surface of the light emitting structure is formed as an inclined surface which creates an acute angle relative to the upper surface of the sapphire substrate.

In this aspect, an irregular pattern may be formed on the upper surface of the sapphire substrate.

In this aspect, the side surface of the light emitting structure, which is formed as the inclined surface, may include grooves formed in a perpendicular direction.

In this aspect, at least one side surface of the sapphire substrate may include at least one modification region in a band shape formed in a horizontal direction.

In this aspect, the modification region may be formed by radiating a laser at a predetermined interval in a horizontal direction onto an upper portion or a lower portion of the semiconductor light emitting device. Also, the modification region may be formed at a position at least 30 μm spaced apart from the upper surface of the substrate having the nitride structure. Also, when the at least one modification region may comprise a plurality of modification regions, the modification regions may be spaced apart from each other by an interval of 40˜90 μm. Also, the laser may be a femto-second or pico-second pulse laser using an infrared source.

In this aspect, the light emitting structure may comprise an n-type nitride semiconductor layer, the active layer, and a p-type nitride semiconductor layer, which are sequentially formed on the upper surface of the sapphire substrate, and may include a hole which is formed at a predetermined distance from the side surface of the light emitting structure so as to expose part of an upper surface of the n-type nitride semiconductor layer. Also, the light emitting structure may further comprise an n-electrode formed on the upper surface of the n-type nitride semiconductor layer exposed by the hole.

In addition, the present invention provides a method of manufacturing a semiconductor light emitting device, comprising forming a light emitting structure comprising a plurality of nitride epitaxial layers including an active layer which produces light on an upper surface of a sapphire substrate, removing a partial region of the light emitting structure thus exposing a predetermined region of the sapphire substrate, and wet etching a side surface of the light emitting structure defined by the exposed region of the sapphire substrate, thus forming an inclined surface which creates an acute angle relative to the upper surface of the sapphire substrate.

In this aspect, the method may further comprise separating the sapphire substrate into discrete unit devices thus forming discrete semiconductor light emitting devices. Also, forming the discrete semiconductor light emitting devices may be carried out in such a manner that a laser which is focused on at least one height inside the sapphire substrate is radiated multiple times at a predetermined interval along a separation surface where the discrete devices are separated from the upper surface or lower surface of the sapphire substrate, thus dividing the sapphire substrate. Also, the height of the focused laser may be a position at least 30 μm spaced apart from the upper surface of the sapphire substrate having the plurality of nitride epitaxial layers. Also, when the at least one height of the focused laser may comprise a plurality of heights, the heights may be positioned separated by an interval of 40˜90 μm. Also, the laser may be a femto-second or pico-second pulse laser using an infrared source.

In this aspect, an irregular pattern may be formed on the upper surface of the sapphire substrate.

In this aspect, removing the partial region of the light emitting structure may be carried out using dry etching or laser irradiation.

In this aspect, forming the light emitting structure may be carried out by sequentially forming an n-type nitride semiconductor layer, the active layer, and a p-type nitride semiconductor layer on the upper surface of the sapphire substrate thus forming the light emitting structure. Also, removing part of the active layer and the p-type nitride semiconductor layer at a position spaced apart from the side surface of the light emitting structure so as to expose part of the upper surface of the n-type nitride semiconductor layer thus forming a hole, and forming an n-electrode on the upper surface of the n-type nitride semiconductor layer exposed by the hole may be further performed.

### Advantageous Effects

According to the present invention, at least one side surface of a light emitting structure of a semiconductor light emitting device is formed as an inclined surface, thereby effectively increasing light extraction efficiency in a lateral direction of the light emitting structure. Furthermore, grooves can be formed in a perpendicular direction on the side surface of the light emitting structure, thus further increasing the light extraction efficiency.

Also according to the present invention, at least one modification region can be formed on at least one side surface of a sapphire substrate of a semiconductor light emitting device to provide irregularities, so that light extraction efficiency can also be increased in a lateral direction of the substrate.

Also according to the present invention, a laser can be radiated at a variety of different heights, whereby a thick sapphire substrate can be easily separated.

### DESCRIPTION OF DRAWINGS

FIG. 1 is a perspective view illustrating a semiconductor light emitting device according to an embodiment of the present invention;

FIG. 2 is a side view illustrating one side surface of the semiconductor light emitting device of FIG. 1;

FIGS. 3 and 4 are side views illustrating one side surface of a semiconductor light emitting device according to a variety of embodiments of the present invention;

FIGS. 5a to 5d are views illustrating the formation of the modification region formed on a sapphire substrate of the semiconductor light emitting device according to the embodiment of the present invention;

FIGS. 6a to 6e are cross-sectional views illustrating a process of manufacturing the semiconductor light emitting device according to an embodiment of the present invention;

FIG. 7 is a scanning electron microscope (SEM) image illustrating one side surface of the semiconductor light emitting device according to the embodiment of the present invention;

FIGS. 8a and 8b are electron microscope images illustrating a top plan view of the semiconductor light emitting device according to the embodiment of the present invention;

FIG. 9 is an image illustrating a side view of the light emitting structure of the semiconductor light emitting device according to the embodiment of the present invention;

FIGS. 10a and 10b are images illustrating the light emission distribution of the semiconductor light emitting device according to the embodiment of the present invention and a typical semiconductor light emitting device.

### MODE FOR INVENTION

Hereinafter, preferred embodiments of the present invention will be described in detail with reference to the accompanying drawings. However, the embodiments of the present invention may be modified into a variety of different forms, and the scope of the present invention is not limited thereto. The embodiments of the present invention are provided to allow the present invention to be more clearly understood by those having ordinary knowledge in the art. Further, in the description of the present invention, the terms defined in consideration of functions in the present invention may vary depending on the usage or intention of technicians who work in the art, and should not be construed as meanings which limit the technical elements of the present invention.

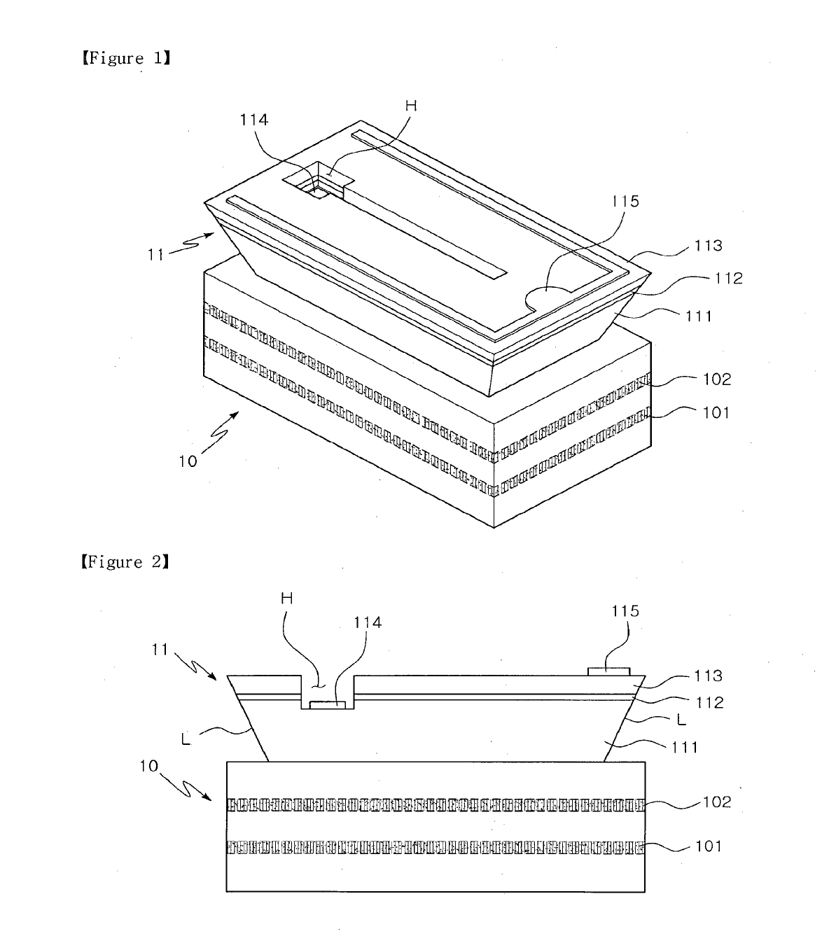

FIG. 1 is a perspective view illustrating a semiconductor light emitting device according town embodiment of the present invention, and FIG. 2 is a side view illustrating one side surface of the semiconductor light emitting device of FIG. 1.

With reference to FIGS. 1 and 2, the semiconductor light emitting device according to the embodiment of the present invention comprises a sapphire substrate 10, and a light emitting structure 11 formed on the upper surface of the sapphire substrate.

The sapphire substrate 10 is applied taking into consideration the lattice matching with a nitride epitaxial layer material which is grown thereon. The sapphire substrate is a crystal body having Hexa-Rhombo (Hexa-Rhombo R3c) symmetry, and has a lattice constant of 13.001 Å in c-axis orientation, and a lattice constant of 4.758 Å in a-axis orientation; and has a C-plane (0001), an A-plane (1120), an R-plane (1102), etc. The C-plane of this sapphire substrate allows a nitride thin film to be grown thereupon relatively easily and is stable even at high temperatures, thus it is predominantly utilized as a substrate for a blue or green light emitting device.

The light emitting structure 11 is formed on the upper surface of the sapphire substrate 10, and may include a light emitting structure comprising a plurality of nitride epitaxial layers including an active layer 112 which produces light. The semiconductor light emitting device according to the embodiment of the present invention is configured such that at least one side surface L of the light emitting structure 11 is formed as an inclined surface which creates an acute angle relative to the upper surface of the sapphire substrate 10.

When the side surface of the light emitting structure 11 is formed as an inclined surface which creates an acute angle relative to the upper surface of the substrate 10 in this way, the incident angle of light which is incident on the side surface of the light emitting structure 11 may be set to he smaller than the critical angle for outer emission which is determined based on the law of refraction, in the light emitting structure. Thereby the amount of light emitted in the lateral direction of the light emitting structure 11 may become larger, thus increasing light extraction efficiency.

The light emitting structure 11 may include an n-type nitride semiconductor layer 111, an active layer 112, and a p-type nitride semiconductor layer 113.

The n-type nitride semiconductor layer 111 is formed with n-type AlₓIn_{y}Ga_{1-x-y}N(0≦x,y,x+y≦1), and may be composed of a nitride semiconductor doped with an n-type impurity. For example, a nitride semiconductor such as GaN, AlGaN or InGaN may be doped with an impurity such as Si, Ge, Se, Te or C.

The active layer 112 is a region where electrons and holes are recombined to emit light, and the wavelength of extracted light is determined depending on the kind of material of the active layer 112. The active layer 112 may have a multiple quantum well (MQW) structure or a single quantum well structure, and a barrier layer and a well layer are a binary compound semiconductor layer to a quaternary compound semiconductor layer represented by AlₓIn_{y}Ga_{1-x-y}N(0≦x, y, x+y≦1). For example, an InGaN layer is grown as the well layer, and the GaN layer is grown as the barrier layer thus forming MQW.

The p-type nitride semiconductor layer 113 is formed with p-type AlₓIn_{y}Ga_{1-x-y}N(0≦x, y, x+y≦1), and may be composed of a semiconductor material doped with a p-type impurity. For example, a nitride semiconductor such as GaN, AlGaN or InGaN may be doped with an impurity such as Mg, Zn or Be.

Typically, the semiconductor light emitting device may include an n-electrode 114 and a p-electrode 115 respectively electrically connected to the n-type nitride semiconductor layer and the p-type nitride semiconductor layer in order to apply a driving voltage and allow inflow of a driving current. In a horizontal type semiconductor light emitting device, the n-electrode may be formed on the n-type nitride semiconductor exposed by removing part of the active layer 112 and the p-type nitride semiconductor layer 113.

According to the embodiment of the present invention, the light emitting structure 11 may include a hole H which is formed at predetermined distances from the side surfaces of the light emitting structure so as to expose part of the upper surface of the n-type nitride semiconductor layer. The n-electrode 114 may be formed on the upper surface of the n-type nitride semiconductor layer 111 exposed by the hole H. The hole H which plays a role in forming a region where the n-electrode is provided is formed at predetermined distances from the side surfaces which are provided in the form of an inclined surface, thereby preventing the deformation of such side surfaces. Consequently, the effect of increasing light extraction efficiency, which may be obtained by forming the side surfaces as an inclined surface, may be prevented from decreasing.

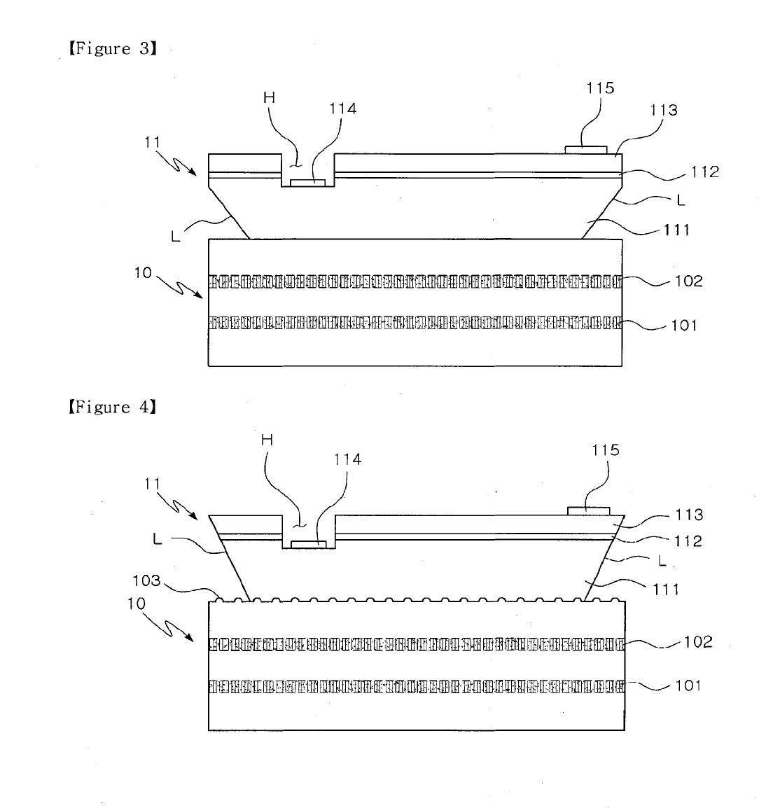

FIGS. 3 and 4 are side views illustrating one side surface of the semiconductor light emitting device according to a variety of embodiments of the present invention.

FIG. 3 illustrates an inclined surface L formed at the lower portion of the side surface of the light emitting structure 11 which is located close to the sapphire substrate 10, and FIG. 4 illustrates an irregular pattern 103 formed on the upper surface of the sapphire substrate 10.

As illustrated in FIG. 3, in the case where the side surface of the light emitting structure 11 is formed as an inclined surface which creates an acute angle relative to the upper surface of the sapphire substrate 10, the light produced from the active layer 112, in particular, light traveling towards the n-type nitride semiconductor layer 111 positioned under the active layer 112, has a much smaller incident angle.

Also as illustrated in FIG. 4, light produced from the active layer 112 is scattered by the irregular pattern 103 formed on the upper surface of the sapphire substrate 10, thus increasing the probability of light being emitted to the outside of the light emitting device to thereby enhance light extraction efficiency. In the embodiment of FIG. 4, comparatively more defects occur in the light emitting structure close to the sapphire substrate 10 due to the irregular pattern 103 formed on the upper surface of the sapphire substrate 10. Because such defects may weaken the molecular bonding structure, in a wet etching process which is used to form a side surface of the light emitting structure 11 into an inclined surface, the etched amount of the region near the sapphire substrate 10 becomes larger thus increasing the gradient. Furthermore, because of a difference in the etched amount between the region having the irregular pattern 103 and the region having no pattern, a plurality of grooves may be formed in a perpendicular direction on the inclined side surface of the light emitting structure 11. These grooves may further increase the light extraction efficiency in the lateral direction of the light emitting structure 11.

In the embodiments illustrated in FIGS. 1 to 4, one or more modification regions 101, 102 may be formed on at least one side surface of the sapphire substrate 10.

The modification regions 101, 102 may be formed by a laser which is radiated in a horizontal direction at predetermined heights inside a wafer, in the course of separating the sapphire substrate in a wafer state. Specifically in FIGS. 1 to 4, the modification regions 101, 102 may be formed by focusing a laser on the corresponding height in the upper or lower portion of the sapphire substrate in a wafer state and radiating such a laser multiple times in a horizontal direction.

The laser which is focused and radiated to the inside of the sapphire substrate 10 may be a femto-second pulse laser or a pico-second pulse laser using an infrared source. The femto-second pulse laser or the pico-second pulse laser using the infrared source may use less filter than an infrared source laser, thus enabling much stronger inner processing and non-thermal processing in a short period of time thereby reducing damage to the device.

In the course of separating the sapphire substrate in a wafer state by the laser to form discrete devices, the laser is radiated onto a separation surface where the discrete devices are separated. After completion of the separation of discrete devices by the laser, the modification regions 101, 102 may be formed on the separation surface.

The modification regions 101, 102 may be formed in a band shape in a horizontal direction on the side surface of the substrate by way of laser irradiation which is performed at a predetermined interval in the horizontal direction of the device.

The modification regions 101, 102 may form irregularities on the side surface of the sapphire substrate 10, so that the inner total reflection of light which is emitted from the inside of the sapphire substrate 10 to, the outside thereof may decrease, thereby increasing the light extraction efficiency in the lateral direction of the device.

The number of modification regions 101, 102 may vary depending on the thickness of the sapphire substrate 10.

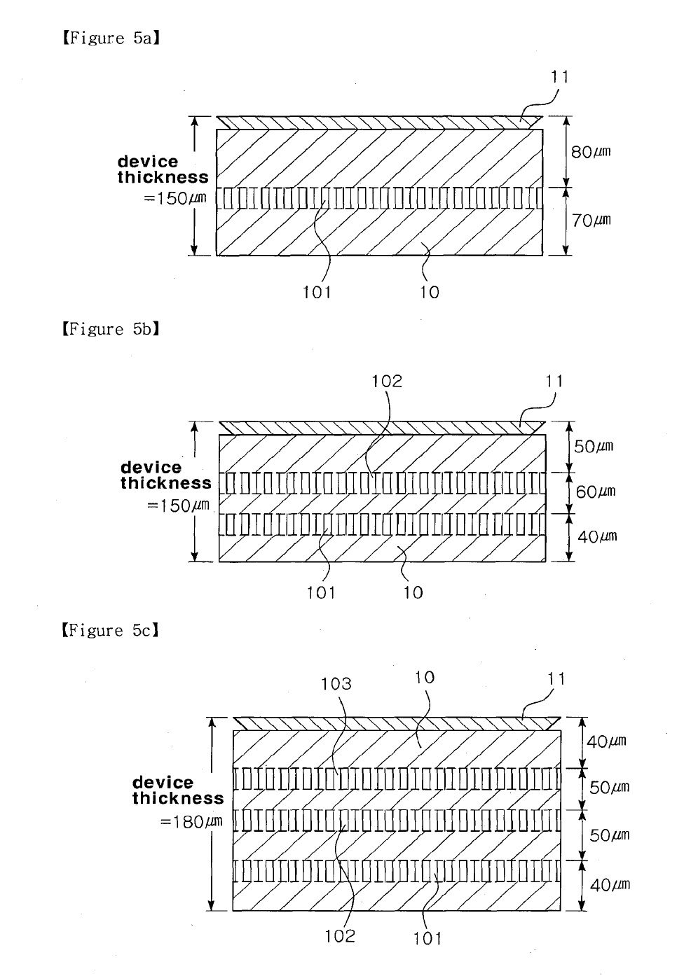

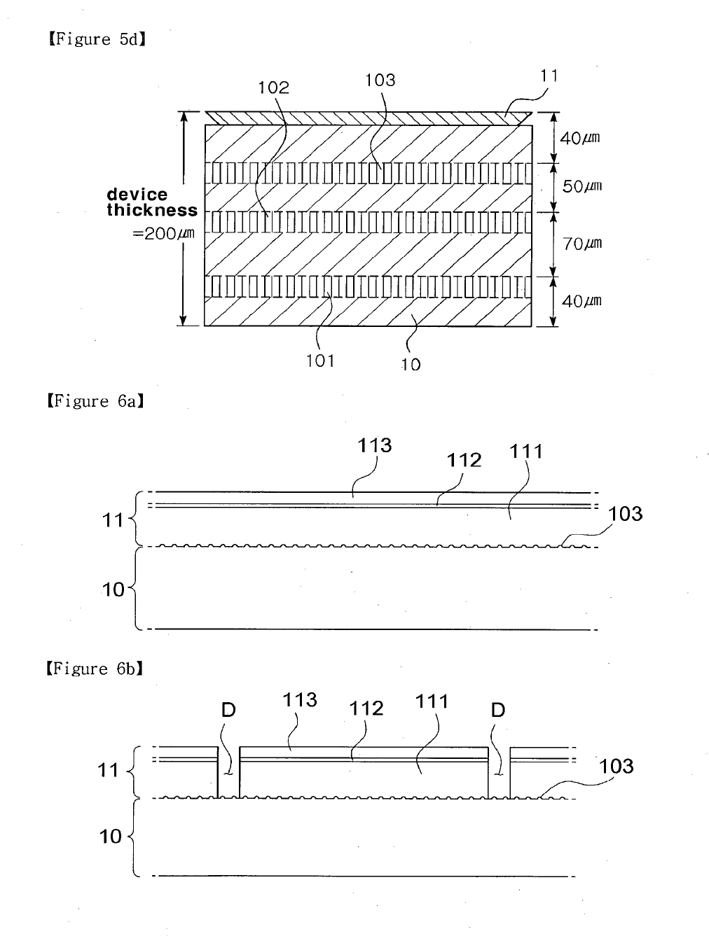

FIGS. 5a to 5d illustrate the formation of the modification regions on the sapphire substrate of the semiconductor light emitting device according to the embodiment of the present invention.

As illustrated in FIGS. 5a and 5b, in the device having a total thickness of 150 μm, a laser is focused at a height of 70 μm from the lower surface of the sapphire substrate 10 and then radiated to form a single modification region 101, or is focused at heights of 40 μm and 100 μm from the lower surface of the sapphire substrate 10 and then radiated to form two modification regions 101, 102.

As illustrated in FIG. 5c, in the device having a total thickness of 180 μm, a laser is focused at heights of 40 μm, 90 μm and 140 μm from the lower surface of the sapphire substrate 10 and then radiated to form three modification regions 101, 102, 103.

Also as illustrated in FIG. 5d, in the device having a total thickness of 200 μm, a laser is focused at heights of 40 μm, 110 μm and 160 μm from the lower surface of the sapphire substrate 10 and then radiated to form three modification regions 101, 102, 103.

According to the embodiment of the present invention, the positions at which a laser is radiated are appropriately adjusted to form modification regions, which may be applied to the separation of a device having different thicknesses. In this procedure, in order to prevent damage to the light emitting structure 11 formed on the sapphire substrate 10, the modification region is preferably formed at a position at least 30 μm spaced apart from the upper surface of the sapphire substrate 10 on which the light emitting structure 11 is formed. Furthermore, in the case where a plurality of modification regions is formed taking into consideration the easy separation of the sapphire substrate and the number of times of irradiation with the laser, respective modification regions may be spaced apart from each other by an interval of 40˜90 μm.

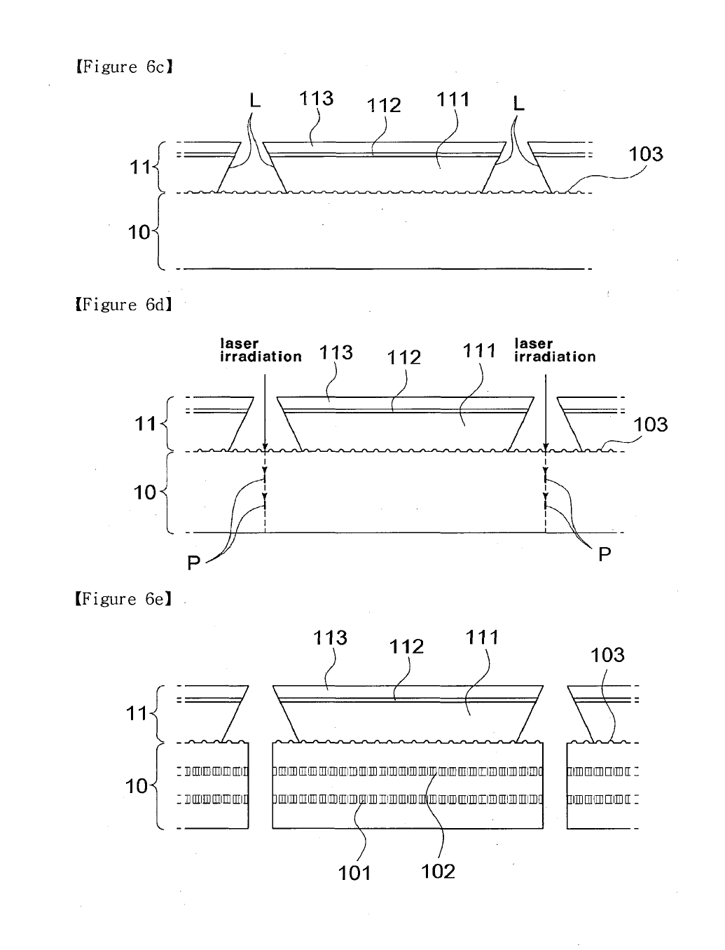

FIGS. 6a to 6e are cross-sectional views illustrating a process of manufacturing the semiconductor light emitting device according to an embodiment of the present invention.

As illustrated in FIG. 6a, the method of manufacturing the semiconductor light emitting device according to the embodiment of the present invention begins from sequentially forming the n-type nitride semiconductor layer 111, the active layer 112 and the p-type nitride semiconductor layer 113 on the upper surface of the sapphire substrate 10 to form the light emitting structure 11. FIGS. 6a to 6e illustrate the use of the sapphire substrate 10 having an irregular pattern 103 formed thereon but the present invention is not limited thereto.

Subsequently, as illustrated in FIG. 6b, the partial regions D of the light emitting structure 11 are removed thus exposing predetermined regions of the sapphire substrate 10. The regions D of the light emitting structure 11 may be used when separating the device into discrete unit devices. The procedure of removing the partial regions of the light emitting structure 11 may be carried out by removing the light emitting structure 11 using dry etching or laser irradiation.

Subsequently, as illustrated in FIG. 6c, the side surfaces of the light emitting structure 11 defined by the exposed regions of the sapphire substrate 10 are wet etched, thus forming inclined surfaces which create an acute angle relative to the upper surface of the sapphire substrate. In this wet etching process, hydroxide (e.g. potassium hydroxide or sodium hydroxide) and an acid-based material (e.g. sulfuric acid, phosphoric acid, nitric acid and mixtures thereof) may be used as an etchant. When the wet etching process is performed in this way, the light emitting structure is etched in a larger amount as it becomes closer to the sapphire substrate which has a comparatively unstable molecular bonding structure, and is etched in a smaller amount as it becomes more distant from the substrate, whereby the side surfaces of the light emitting structure may be formed as inclined surfaces.

Subsequently, in order to separate into discrete unit devices, as illustrated in FIG. 6d, a focused laser may be radiated onto specific positions P inside the sapphire substrate 10. The procedure illustrated in FIG. 6d is carried out in such a manner that a laser focused on at least one height P inside the sapphire substrate 10 is radiated multiple times at predetermined intervals along the separation surface where discrete unit devices are separated from the upper surface or lower surface of the sapphire substrate 10, so that the sapphire substrate is divided. When the inside of the sapphire substrate 10 is irradiated with the focused laser in this way, the modification regions may be formed on the side surfaces of the sapphire substrate of the discrete unit devices.

As illustrated in FIG. 6e after the procedures of FIGS. 6a to 6d, the modification regions 101, 102 are formed on the side surfaces of the sapphire substrate 10, and the side surfaces of the light emitting structure 11 may be formed as inclined surfaces which create an acute angle relative to the upper surface of the sapphire substrate 10.

Although not shown, the method of manufacturing the semiconductor light emitting device according to the embodiment of the present invention may further comprise forming n-electrodes and p-electrodes of discrete unit devices.

For example, before the sapphire substrate 10 is separated into discrete unit devices by the procedure illustrated in FIG. 6d, electrodes may be formed. In particular, forming the n-electrode may be carried out by removing part of the active layer 112 and the p-type nitride semiconductor layer 113 at a position spaced apart from the side surfaces of the light emitting structure so as to expose part of the upper surface of the n-type nitride semiconductor layer 111 thus forming a hole (H in FIGS. 1 to 4), and forming the n-electrode (114 in FIGS. 1 to 4) on the upper surface of the n-type nitride semiconductor layer 111 exposed by the hole.

Below is a description of the effects of the present invention made through the actual images of the semiconductor light emitting device according to the embodiment of the present invention.

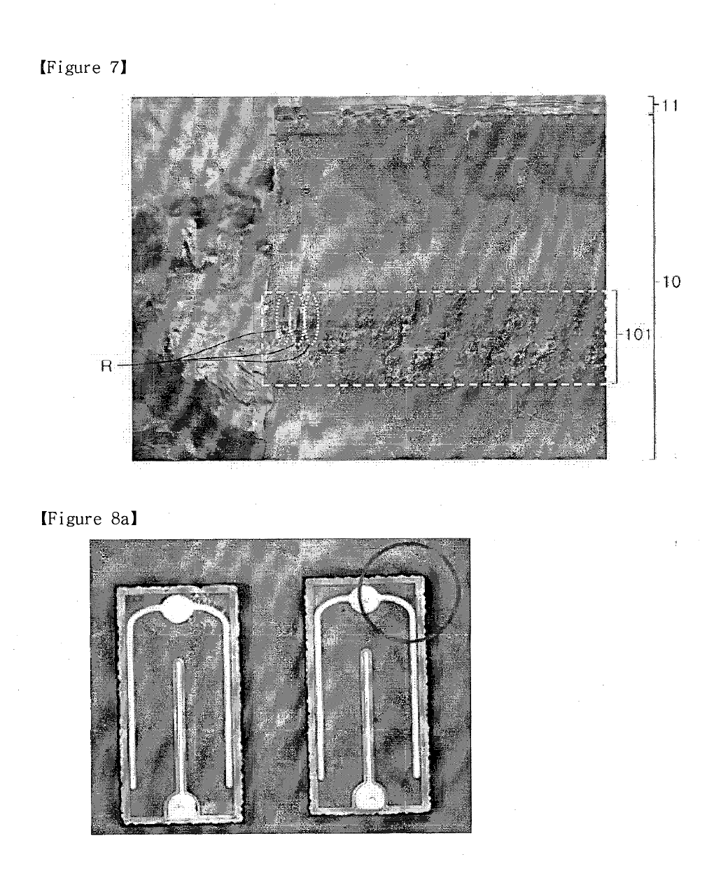

FIG. 7 is an SEM image illustrating one side surface of the semiconductor light emitting device according to the embodiment of the present invention.

As seen in FIG. 7, the reference numeral 10 designates the substrate, and the reference numeral 11 designates the light emitting structure, and the reference numeral 101 designates the modification region. As mentioned above, the modification region 101 is formed in such a manner that a femto-second laser or a pico-second laser using an infrared source is radiated multiple times at a predetermined interval in a horizontal direction onto the upper or lower surface of the substrate 10. In FIG. 7, the portion represented by R indicates a region on which a laser is directly radiated, and the modification region in which the properties of sapphire are different is formed by absorbing energy of the laser around the region irradiated with the laser. The modification region formed in the substrate by way of laser irradiation is exposed on the side surfaces of the separated discrete devices. The random irregular shape of the modification region enables the incident angle of light which is incident on the modification region in the device to vary to thus reduce the inner total reflection thereof thereby increasing the lateral light extraction efficiency of the sapphire substrate.

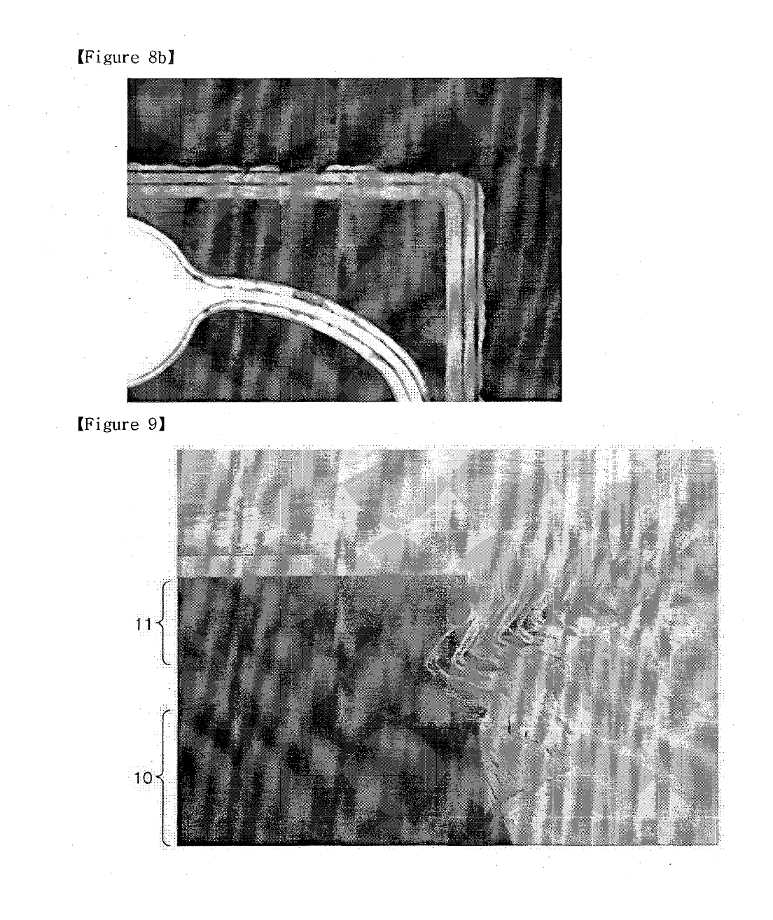

FIGS. 8a and 8b are electron microscope images showing a top plan view of the semiconductor light emitting device according to the embodiment of the present invention, and FIG. 9 is an electron microscope image showing a side view of the light emitting structure of the semiconductor light emitting device according to the embodiment of the present invention.

As illustrated in FIGS. 8a, 8b and 9, the side surfaces of the light emitting structure 11 may be formed as inclined surfaces using wet etching, and grooves having a non-uniform shape may be formed in a perpendicular direction due to a difference in the amount of etching. The side surfaces of the light emitting structure may include random irregularities due to such grooves, and these irregularities enable the incident angle of light which is incident in the lateral direction of the device to vary thus reducing the inner total reflection and increasing the lateral light extraction efficiency.

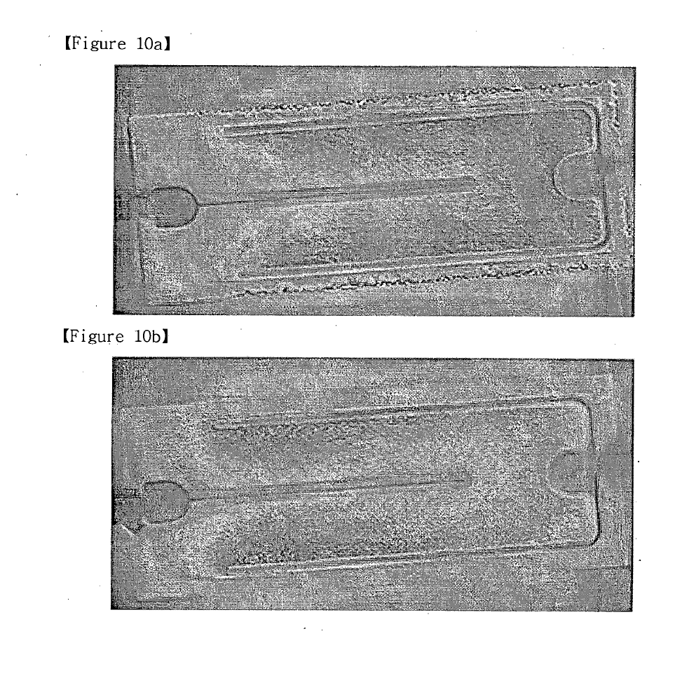

FIGS. 10a and 10b illustrate the light emission distribution of the semiconductor light emitting device according to the embodiment of the present invention and a typical semiconductor light emitting device.

As illustrated in FIG. 10a, the semiconductor light emitting device according to the embodiment of the present invention can be seen to achieve a large amount of light emission from the side surfaces of the light emitting device. However, it can be seen that the typical semiconductor light emitting device illustrated in FIG. 10b exhibits very weak lateral light emission.

As described above, the side surfaces of the light emitting structure of the semiconductor light emitting device according to embodiments of the present invention are formed as inclined surfaces, thus increasing light extraction efficiency in the lateral direction of the light emitting structure. In particular, grooves are formed in a perpendicular direction on the side surfaces of the light emitting structure thus further increasing the light extraction efficiency. Also according to one embodiment of the present invention, modification regions are formed on the side surfaces of the sapphire substrate of the semiconductor light emitting device to provide irregularities, thus increasing the light extraction efficiency in the lateral direction of the substrate. Moreover, according to one embodiment of the present invention, when the sapphire substrate is separated, a laser can be radiated at different heights thus enabling a thick sapphire substrate to be easily divided.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1-18. (canceled)

19. A semiconductor light emitting device, comprising:
a patterned substrate including a first region and a second region surrounding the first region; and
a light emitting structure disposed on the first region of the patterned substrate and including a first nitride semiconductor layer, a second nitride semiconductor, and an active layer between the first and second nitride semiconductors, wherein the light emitting structure is structured to expose a portion of the light emitting structure;
a first electrode formed on the exposed portion of the light emitting structure to be positioned on a upper surface of the first nitride semiconductor layer; and
a second electrode formed on the non-exposed portion of the light emitting structure to be positioned on a upper surface of the second nitride semiconductor,
wherein the exposed portion of the light emitting structure extends to the second electrode.

20. The semiconductor light emitting device of claim 19, wherein the exposed portion is spaced apart from the second electrode.

21. The semiconductor light emitting device of claim 19, wherein the exposed portion is spaced apart from a side surface of the light emitting structure.

22. The semiconductor light emitting device of claim 19, wherein the light emitting structure includes an inclined side surface forming an acute angle with respect to a surface of the patterned substrate.

23. The semiconductor light emitting device of claim 19, wherein the patterned substrate includes a sapphire.

24. The semiconductor light emitting device of claim 19, wherein the patterned substrate includes at least one modification region formed in a horizontal direction to provide irregularities on the side surface of the patterned substrate.

25. The semiconductor light emitting device of claim 24, when the patterned substrate includes two or more modification regions, the modification regions are spaced apart from one another in a vertical direction.

26. The semiconductor light emitting device of claim 19, wherein the patterned substrate includes irregularities formed on an upper surface of the patterned substrate.

27. The semiconductor light emitting device of claim 19, wherein the light emitting structure includes a side surface having grooves formed thereon.

28. A semiconductor light emitting device, comprising:
a substrate;
a light emitting structure formed over the substrate and including a first semiconductor layer, a second semiconductor layer, and an active layer formed between the first and second semiconductor layers, wherein the light emitting structure includes a side surface operated to make an incident angle of light incident on the side surface of the light emitting structure smaller than a critical angle for an outer emission of the side surface of the light emitting structure and the light emitting structure is structured to expose a portion of the first semiconductor layer;
a first electrode formed on the exposed portion of the first semiconductor layer; and
a second electrode formed on an upper surface of the second semiconductor layer.

29. The semiconductor light emitting device of claim 28, wherein the side surface is inclined to form an acute angle with respect to a surface of the substrate.

30. The semiconductor light emitting device of claim 28, wherein the exposed portion of the first semiconductor layer is positioned to be spaced apart from a side surface of the light emitting structure.

31. The semiconductor light emitting device of claim 28, wherein the inclined side surface includes an inclined portion at a lower portion of the side surface and a non-inclined portion at an upper portion of the side surface.

32. The semiconductor light emitting device of claim 28, wherein the substrate includes patterns formed on an upper surface of the substrate.

33. The semiconductor light emitting device of claim 28, wherein the substrate includes at least one modification region formed in a horizontal direction to provide irregularities on the side surface of the patterned substrate.

34. The semiconductor light emitting device of claim 33, when the substrate includes two or more modification regions, the modification regions are spaced apart from one another in a vertical direction.

35. The semiconductor light emitting device of claim 28, wherein the inclined side surface of the light emitting structure includes grooves formed thereon.
